(19) United States
(12) Patent Application Publication
(10) Pub. No.: US 2025/0149515 A1
(43) Pub. Date: May 8, 2025

(54) SEMICONDUCTOR PACKAGES

(71) Applicant: SAMSUNG ELECTRONICS CO., LTD., Suwon-si (KR)

(72) Inventors: Kiju LEE, Suwon-si (KR); Jinwoo PARK, Suwon-si (KR)

(21) Appl. No.: 18/673,864

(22) Filed: May 24, 2024

(30) Foreign Application Priority Data
Nov. 6, 2023 (KR) 10-2023-0151763
Nov. 23, 2023 (KR) 10-2023-0164152

(51) Int. Cl. H01L 25/10; H01L 23/00; H01L 23/31; H01L 23/373; H01L 23/498

(52) U.S. Cl. CPC H01L 25/105; H01L 23/3135; H01L 23/3736; H01L 23/49822; H01L 23/49838; H01L 24/29; H01L 24/32; H01L 24/73; H01L 24/16; H01L 24/48; H01L 2224/16227; H01L 2224/16238; H01L 2224/29166; H01L 2224/2957; H01L 2224/29647; H01L 2224/32145; H01L 2224/32227; H01L 2224/48227; H01L 2224/73204; H01L 2224/73253; H01L 2224/73265; H01L 2225/1023; H01L 2225/1035; H01L 2225/1041; H01L 2225/1058; H01L 2225/1094; H01L 2924/3511

(57) ABSTRACT

A semiconductor package, comprising: a semiconductor chip; a conductive bonding layer on the semiconductor chip; an upper insulating layer on the conductive bonding layer; an upper package on the upper insulating layer; a heat dissipation structure that includes upper heat dissipation patterns and upper heat dissipation vias, wherein the upper heat dissipation patterns are in the upper insulating layer, and the upper heat dissipation vias connect the conductive bonding layer and the upper heat dissipation patterns; and a heat dissipation member on at least one side of the upper package, wherein the heat dissipation member is connected to the upper heat dissipation patterns.

### CROSS-REFERENCE TO RELATED APPLICATIONS

This application claims benefit of priority to Korean Patent Application Nos. 10-2023-0151763, filed on Nov. 6, 2023 in the Korean Intellectual Property Office and 10-2023-0164152, filed on Nov. 23, 2023 in the Korean Intellectual Property Office, the inventive concepts of which are incorporated herein by reference in its entirety.

### BACKGROUND OF THE INVENTION

The present inventive concept relates to a semiconductor package.

In accordance with the implementation of lightweightedness and high performance in electronic devices, miniaturized and high performance semiconductor chips are needed to be developed. In order to improve reliability of high-performance semiconductor chips, the importance of heat dissipation characteristics of semiconductor packages is increasing.

### SUMMARY OF THE INVENTION

An aspect of the present inventive concept is to provide semiconductor packages having improved reliability.

According to aspects of the present inventive concept, a semiconductor package, may include: a semiconductor chip structure that includes a semiconductor chip and a conductive bonding layer on an upper surface of the semiconductor chip; a lower redistribution structure on a lower surface of the semiconductor chip structure, wherein the lower redistribution structure includes a lower insulating layer and lower redistribution layers in the lower insulating layer; external connection bumps on a lower surface of the lower redistribution structure, wherein the external connection bumps are electrically connected to the lower redistribution layers; an encapsulant on the semiconductor chip structure and the lower redistribution structure; an upper redistribution structure on the semiconductor chip structure, wherein the upper redistribution structure includes an upper insulating layer, upper redistribution layers in the upper insulating layer, and upper redistribution vias that electrically connect the upper redistribution layers to each other; an interconnection structure in the encapsulant, wherein the interconnection structure electrically connects the lower redistribution layers and the upper redistribution layers; a heat dissipation structure that includes upper heat dissipation patterns and upper heat dissipation vias, wherein the upper heat dissipation patterns are in the upper insulating layer, and the upper heat dissipation vias connect the conductive bonding layer and the upper heat dissipation patterns; an upper package on the upper redistribution structure, wherein the upper package is electrically connected to the upper redistribution layers; and a heat dissipation member on at least one side of the upper package, wherein the heat dissipation member is connected to the upper heat dissipation patterns.

According to aspects of the present inventive concept, a semiconductor package, may include: a lower redistribution structure that includes lower redistribution layers; a semiconductor chip structure on the lower redistribution structure; an encapsulant on the semiconductor chip structure and the lower redistribution structure; an upper redistribution structure that includes an upper insulating layer and upper redistribution layers, wherein the upper insulating layer is on the encapsulant, and the upper redistribution layers are on and within the upper insulating layer; a heat dissipation structure that includes upper heat dissipation patterns and upper heat dissipation vias, wherein the upper heat dissipation patterns are on and within the upper insulating layer, and the upper heat dissipation vias are in the upper insulating layer; and a heat dissipation member on the upper redistribution structure, wherein the heat dissipation member is connected to the upper heat dissipation patterns, wherein the upper redistribution layers include an uppermost upper redistribution layer on the upper insulating layer, wherein the upper heat dissipation patterns include an uppermost upper heat dissipation pattern on the upper insulating layer, and wherein a width of an upper surface of the uppermost upper heat dissipation pattern is greater than a width of an upper surface of the uppermost upper redistribution layer.

According to aspects of the present inventive concept, a semiconductor package, may include: a first semiconductor package including a first semiconductor chip structure; a first encapsulant that extends around the first semiconductor chip structure; an upper redistribution structure that includes an upper insulating layer and upper redistribution layers on and within the upper insulating layer, wherein the upper redistribution structure is on an upper surface of the first semiconductor chip structure and an upper surface of the first encapsulant; and a heat dissipation structure that includes upper heat dissipation patterns and upper heat dissipation vias, wherein the upper heat dissipation patterns are on and within the upper insulating layer, and the upper heat dissipation vias connect ones among the upper heat dissipation patterns to each other in the upper insulating layer; a second semiconductor package on the first semiconductor package; wherein the second semiconductor package includes a redistribution substrate that includes a signal pattern, a power pattern, and a ground pattern; a second semiconductor chip structure on the redistribution substrate, wherein the second semiconductor chip structure is electrically connected to the signal pattern, the power pattern, and the ground pattern; a second encapsulant on the second semiconductor chip structure; and connection conductors on a lower surface of the redistribution substrate, wherein the connection conductors include a first group of connection conductors and a second group of connection conductors, the first group of connection conductors are electrically connected to at least one of the signal pattern and the power pattern, and the second group of connection conductors are electrically connected to the ground pattern, wherein the first group of connection conductors are electrically connected to the upper redistribution layers, and wherein the second group of connection conductors are connected to the heat dissipation structure.

### BRIEF DESCRIPTION OF DRAWINGS

The above and other aspects, features, and advantages of the present disclosure will be more clearly understood from the following detailed description, taken in conjunction with the accompanying drawings:

FIG. 1A is a cross-sectional view illustrating a semiconductor package according to example embodiments;

FIG. 1B is a plan view illustrating a semiconductor package according to example embodiments;

FIG. 1C is a plan view illustrating a semiconductor package according to example embodiments;

FIG. 1D is an enlarged view of region ‘A’ in FIG. 1A;

FIGS. 2A and 2B are enlarged views of variations of region ‘A’ in FIG. 1A;

FIG. 3A is a cross-sectional view illustrating a semiconductor package according to example embodiments;

FIG. 3B is an enlarged view of region ‘B’ in FIG. 3A;

FIG. 4 is a cross-sectional view illustrating a semiconductor package according to example embodiments;

FIG. 5A is a cross-sectional view illustrating a semiconductor package according to example embodiments;

FIG. 5B is a plan view illustrating a semiconductor package according to example embodiments;

FIG. 6 is a cross-sectional view illustrating a semiconductor package according to example embodiments;

FIG. 7 is a cross-sectional view illustrating a semiconductor package according to example embodiments;

FIG. 8 is a cross-sectional view illustrating a semiconductor package according to example embodiments;

FIGS. 9A to 9D are diagrams of a process sequence illustrating a method of manufacturing a semiconductor chip structure according to example embodiments; and

FIGS. 10A to 10I are diagrams of a process sequence illustrating a method of manufacturing a semiconductor package according to example embodiments.

### DETAILED DESCRIPTION

Hereinafter, embodiments of the present inventive concept will be described with reference to the attached drawings. Hereinafter, terms such as ‘upper,’ ‘upper portion,’ ‘upper surface,’ ‘lower,’ ‘lower portion,’ ‘lower surface,’ ‘side surface,’ and the like, may be understood as referring to the drawings, unless otherwise indicated by reference numerals.

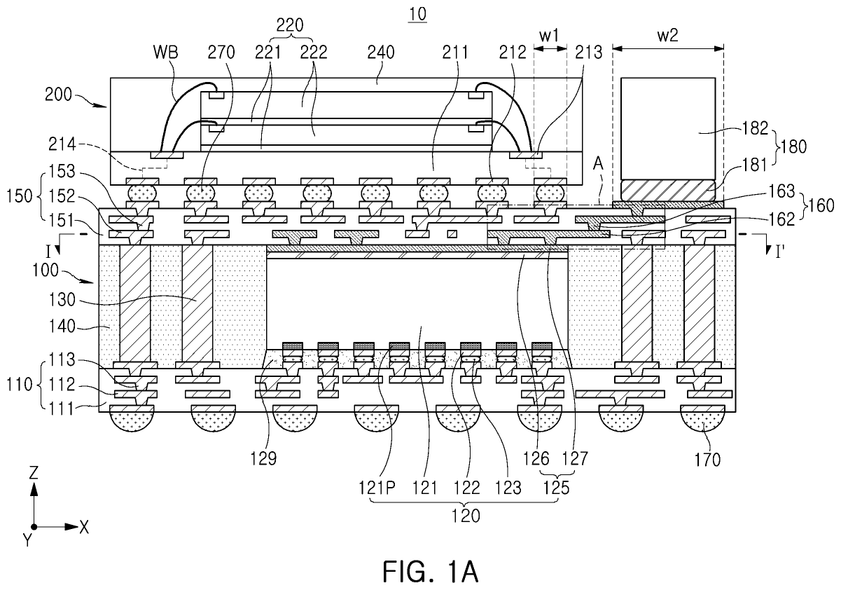

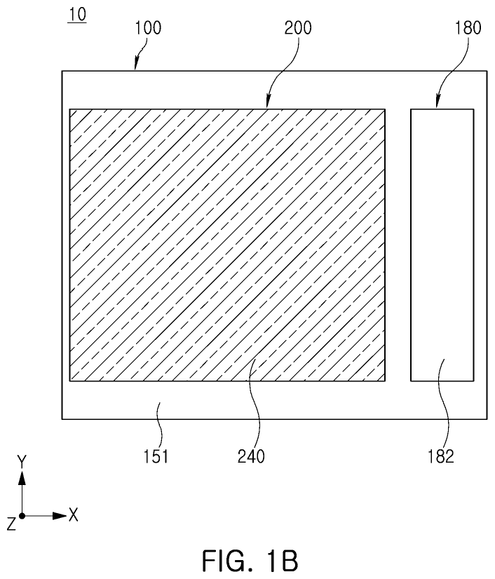

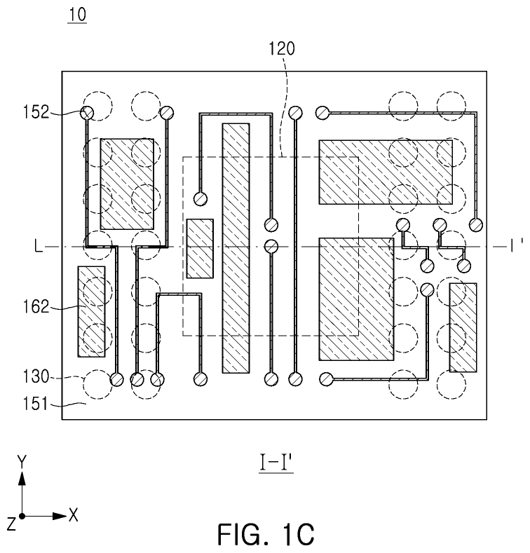

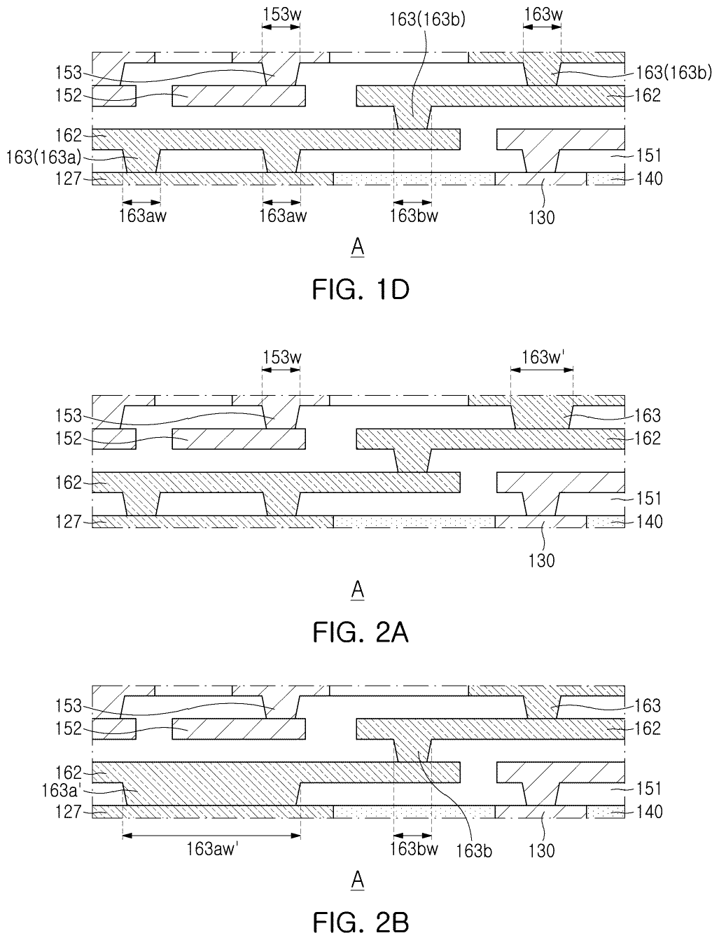

FIG. 1A is a cross-sectional view illustrating a semiconductor package 10 according to example embodiments. FIG. 1B is a plan view illustrating a semiconductor package 10 according to example embodiments. FIG. 1B is a plan view of the semiconductor package 10 according to the example embodiment of FIG. 1A, and only some components are illustrated for convenience of explanation. FIG. 1C schematically illustrates a cross-section cut along the cutting line I-I′ of FIG. 1A. A cross-section cut along the cutting line L-L′ in FIG. 1C may be illustrated as (at least a portion of) FIG. 1A. FIG. 1D is an enlarged view of region ‘A’ of the semiconductor package 10 according to the embodiment of FIG. 1A.

Referring to FIGS. 1A to 1D, the semiconductor package 10 according to an example embodiment may include a first semiconductor package 100 and a second semiconductor package 200. The first semiconductor package 100 may include a lower redistribution structure 110, a semiconductor chip structure 120, an interconnection structure 130, an encapsulant 140, an upper redistribution structure 150, a heat dissipation structure 160, external connection bumps 170, and a heat dissipation member 180. The second semiconductor package 200 may include a redistribution substrate 211, a second semiconductor chip structure 220, and a second encapsulant 240. The first semiconductor package 100 may be referred to as a lower semiconductor package 100, and the second semiconductor package 200 may be referred to as an upper semiconductor package 200. The second semiconductor package 200 may be disposed on the first semiconductor package 100.

The lower redistribution structure 110 may include a lower insulating layer 111, lower redistribution layers 112, and lower redistribution vias 113. The lower redistribution structure 110 may be a support substrate on which the semiconductor chip structure 120 is mounted.

The lower insulating layer 111 may include, for example, an insulating resin. The insulating resin may include, for example, a thermosetting resin such as an epoxy resin, a thermoplastic resin such as polyimide, or a resin impregnated with an inorganic filler such as prepreg, Ajinomoto Build-up Film (ABF), FR-4, and Bismaleimide-Triazine (BT). For example, the lower insulating layer 111 may include a photosensitive resin such as PID (Photo-Imageable Dielectric). The lower insulating layer 111 may include a plurality of insulating layers (not shown) stacked in a vertical direction (e.g., Z-axis direction). The vertical direction may be perpendicular to an upper surface (or a lower surface) of the redistribution structure 110. Depending on the process, boundaries between the plurality of insulating layers (not shown) may be unclear (or invisible).

The lower redistribution layers 112 may be disposed on or within the lower insulating layer 111 and may redistribute (e.g., electrically redistribute) a connection terminal 121P (or a signal that is input or output through the connection terminal 121P) of the semiconductor chip structure 120, which will be described later in detail. The lower redistribution layers 112 may include, for example, copper (Cu), aluminum (Al), silver (Ag), tin (Sn), gold (Au), nickel (Ni), lead (Pb), titanium (Ti), and/or metal containing alloys thereof. The lower redistribution layers 112 may perform various functions depending on the design. For example, the lower redistribution layers 112 may include a ground (GND) pattern, a power (PWR) pattern, and a signal(S) pattern. Here, the signal(S) pattern may be defined as a transmission path for various signals, for example, data signals, or the like, excluding the ground (GND) pattern, power (PWR) pattern, and the like. The lower redistribution layers 112 may include more or fewer redistribution layers than shown in the drawing. The lower redistribution layers 112 disposed on an upper surface of the lower insulating layer 111 may be electrically connected to the plurality of interconnection structures 130 and the connection terminals 121P of the semiconductor chip structure 120. It will be understood that when an element or layer is referred to as being “connected to”, or “coupled to”, another element or layer, it may be directly on, connected to, or coupled to the other element or layer, or one or more intervening elements or layers may be present. In contrast, when an element is referred to as being “directly coupled”, “directly connected”, or “directly responsive” to, or “directly on”, another element, there are no intervening elements present. In addition, “electrical connection”, “electrical distribution”, or “electrical redistribution” conceptually includes a physical connection and a physical disconnection. As used herein, the term “and/or” includes any and all combinations of one or more of the associated listed items. Expressions such as “at least one of,” when preceding a list of elements, modify the entire list of elements and do not modify the individual elements of the list.

The lower redistribution vias 113 may extend vertically (e.g., may extend in Z-axis direction) in the lower insulating layer 111 and be electrically connected to the lower redistribution layers 112. For example, the lower redistribution vias 113 may interconnect the lower redistribution layers 112 at different levels. The lower redistribution vias 113 may include a signal via, a ground via, and a power via. The lower redistribution vias 113 may include, for example, copper (Cu), aluminum (Al), silver (Ag), tin (Sn), gold (Au), nickel (Ni), lead (Pb), titanium (Ti), and/or a metal material including alloys thereof. The lower redistribution vias 113 may be filled vias in which an interior of a via hole is filled (e.g., entirely filled) with a metal material or conformal vias in which a metal material extends along an inner wall of a via hole (or conformal vias in which a metal material partially fills a via hole). Herein, the term, “level”, “height”, or the like may refer to a relative location (e.g., distance) from a lower surface of the lower insulating layer 111 in the vertical direction (e.g., Z-axis direction). For example, if element A is at a higher level than element B, it may mean that element A is farther from the lower surface of the lower insulating layer 111 than element B is in the vertical direction.

The semiconductor chip structure 120 may be disposed on the lower redistribution structure 110 and include a semiconductor chip 121, a connection terminal 121P, a connection pillar 122, a connection solder 123, and a conductive bonding layer 125.

The semiconductor chip 121 may be disposed on an upper surface of the lower redistribution structure 110 and may include a connection terminal 121P electrically connected to the lower redistribution layers 112. The semiconductor chip 121 may be referred to as a first semiconductor chip 121 or a lower semiconductor chip 121. The semiconductor chip 121 may include a semiconductor wafer and/or a semiconductor integrated circuit (IC) including (e.g., formed of) a semiconductor element such as silicon, germanium, and/or a compound semiconductor such as silicon carbide (SiC), gallium arsenide (GaAs), indium arsenide (InAs), and indium phosphide (InP). The semiconductor chip 121 may be a bare integrated circuit (IC) without separate bumps of wiring layers, but the present inventive concept is not limited thereto, and may be a packaged-type integrated circuit. The (semiconductor) integrated circuit (IC) may include a logic circuit (or ‘logic chip’) and/or a memory circuit (or ‘memory chip’). The logic circuit may include, for example, a central processor (CPU), graphics processor (GPU), field programmable gate array (FPGA), application processor (AP), digital signal processor, cryptographic processor, microprocessor, microcontroller, analog-to-digital converter, and/or application-specific IC (ASIC). The memory circuit may include, for example, a volatile memory such as dynamic RAM (DRAM), static RAM (SRAM), and the like and/or a non-volatile memory such as phase change RAM (PRAM), magnetic RAM (MRAM), resistive RAM (RRAM), flash memory, and the like.

The semiconductor chip structure 120 may include a connection pillar 122 and a connection solder 123 connecting (e.g., electrically connecting) the connection terminal 121P to the lower redistribution layer 112 disposed on or in the lower insulating layer 111. An underfill layer 129 may be disposed between the semiconductor chip 121 and the lower redistribution structure 110. The underfill layer 129 may have a capillary underfill (CUF) structure, but the present inventive concept is not limited thereto. Depending on the embodiment, the underfill layer 129 may have a molded underfill (MUF) structure integrated with the encapsulant 140. The underfill layer 129 may extend around (e.g., surround) the connection pillar 122, the connection solder 123, and/or the lower redistribution layer 112 (e.g., the uppermost lower redistribution layer 112). For example, the connection pillar 122, the connection solder 123, and/or the lower redistribution layer 112 (e.g., the uppermost lower redistribution layer 112) may extend in the underfill layer 129.

The semiconductor chip structure 120 may include a conductive bonding layer 125 disposed on an upper surface of the semiconductor chip 121. The conductive bonding layer 125 may include a plurality of layers. In an example embodiment, the conductive bonding layer 125 may include a titanium (Ti) layer 126 in contact with the upper surface of the semiconductor chip 121 and a copper (Cu) layer 127 on the titanium (Ti) layer 126. However, the conductive bonding layer 125 materials are not limited to titanium and copper. An upper surface of the conductive bonding layer 125 (e.g., an upper surface of the copper layer 127) may be exposed from the encapsulant 140 and may be (substantially) coplanar with an upper surface of the encapsulant 140. The conductive bonding layer 125 may (partially or entirely) cover (overlap) the upper surface of the semiconductor chip 121, and the conductive bonding layer 125 may be in direct contact with the upper redistribution structure 150. The conductive bonding layer 125 may be connected (e.g., directly connected) to the heat dissipation structure 160, and heat generated by the semiconductor chip 121 may be transmitted along (or to) the heat dissipation structure 160 through the conductive bonding layer 125.

The interconnection structure 130 may be in (e.g., extend in or penetrate through) the encapsulant 140 to (electrically) connect the lower redistribution layers 112 and the upper redistribution layers 152 (and/or the upper redistribution vias 153), which will be described later in detail. The interconnection structure 130 may extend in the vertical direction (e.g., Z-axis direction) within the encapsulant 140. An upper surface of the interconnection structure 130 may be exposed from the encapsulant 140, and may be (substantially) coplanar with an upper surface of the encapsulant 140. The upper surface of the interconnection structure 130 may not be covered by the encapsulant 140. For example, the interconnection structure 130 may have a post (or a pillar) shape penetrating through the encapsulant 140. However, the shape of the interconnection structure 130 is not limited thereto. The interconnection structure 130 may include, for example, a metal material such as copper (Cu). Depending on the embodiment, a metal seed layer (not shown) containing, for example, titanium (Ti), copper (Cu), and the like may be disposed on a lower surface of the interconnection structure 130.

The encapsulant 140 may extend around (e.g., surround or encapsulate) at least a portion of the semiconductor chip structure 120 on an upper surface of the lower redistribution structure 110. The encapsulant 140 may include, for example, a thermosetting resin such as an epoxy resin, a thermoplastic resin such as polyimide, and/or a resin impregnated with an inorganic filler such as prepreg, ABF, FR-4, BT, and an Epoxy Molding Compound (EMC). For example, the encapsulant 140 may include EMC.

The upper redistribution structure 150 may be disposed on the semiconductor chip structure 120 and the encapsulant 140, and may include an upper insulating layer 151, upper redistribution layers 152, and upper redistribution vias 153.

The upper insulating layer 151 may include an insulating resin. The insulating resin may include a thermosetting resin such as an epoxy resin, a thermoplastic resin such as polyimide, and/or a resin impregnated with an inorganic filler, such as prepreg, ABF, FR-4, BT, and PID. The upper insulating layer 151 may include a plurality of layers stacked in the vertical direction (Z-axis direction). Depending on the process, boundaries between a plurality of layers may be unclear (or invisible).

The upper redistribution layers 152 may be disposed on or within the upper insulating layer 151, and may redistribute (e.g., electrically redistribute) the interconnection structure 130 (e.g., a signal that is input and/or output through the interconnection structure 130). The upper redistribution layer 152 disposed on the upper insulating layer 151 may be referred to as an uppermost upper redistribution layer 152. The upper redistribution layer 152 may include, for example, copper (Cu), aluminum (Al), silver (Ag), tin (Sn), gold (Au), nickel (Ni), lead (Pb), titanium (Ti), and/or a metal material including alloys thereof. The upper redistribution layers 152 may include more or fewer redistribution layers than shown in the drawing. The upper redistribution layers 152 disposed on the upper surface of the upper insulating layer 151 may be physically and electrically connected to an external device. For example, the uppermost upper redistribution layer 152 may be (electrically) connected to the second semiconductor package 200. A barrier layer (not shown) may be disposed on surfaces of the upper redistribution layers 152 on the upper insulating layer 151 (e.g., on surfaces of the uppermost upper redistribution layer 152). As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The upper redistribution vias 153 may be in (e.g., may vertically extend in or penetrate) the upper insulating layer 151 and be electrically connected to the upper redistribution layers 152. For example, the upper redistribution vias 153 may interconnect upper redistribution layers 152 at different levels. The upper redistribution via 153 may be a filled via in which an interior of a via hole is filled (e.g., entirely filled) with a metal material or a conformal via in which a metal material extends along an inner wall of a via hole (or a conformal via in which a metal material partially fills a via hole).

The heat dissipation structure 160 may include upper heat dissipation patterns 162 and upper heat dissipation vias 163.

The upper heat dissipation patterns 162 may be disposed on or within the upper insulating layer 151. The upper heat dissipation pattern 162 disposed on the upper insulating layer 151 may be referred to as an uppermost upper heat dissipation pattern 162. Referring to FIG. 1C, the upper heat dissipation patterns 162 may be disposed at substantially the same level as the upper redistribution layers 152. For example, at least a portion of the upper heat dissipation patterns 162 may be at the same or substantially the same level as at least a portion of the upper redistribution layers 152. The upper heat dissipation patterns 162 may be spaced apart from the upper redistribution layers 152 (in a horizontal direction such as X-axis direction and/or Y-axis direction). The horizontal direction may be parallel with an upper surface (or a lower surface) of the lower redistribution structure 110. Unlike the upper redistribution layers 152, the upper heat dissipation patterns 162 may have a pad shape extending in an X-axis and/or Y-axis direction. For example, (each of) upper surfaces of the upper heat dissipation patterns 162 may have a quadrangular (e.g., a rectangular or a square) shape. The upper heat dissipation patterns 162 may be interconnected by upper heat dissipation vias 163 to transfer heat generated by the semiconductor chip 121 externally of the semiconductor package 10 (e.g., externally of the semiconductor chip 121). The upper heat dissipation patterns 162 may have a pad shape and may prevent or alleviate warpage of the semiconductor package 10. The upper heat dissipation patterns 162 may include, for example, copper (Cu), aluminum (Al), silver (Ag), tin (Sn), gold (Au), nickel (Ni), lead (Pb), titanium (Ti), and/or a metal material including alloys thereof. The upper heat dissipation patterns 162 may include more or fewer heat dissipation patterns (in pad shapes) than shown in the drawing. The upper heat dissipation patterns 162 may be spaced apart from the conductive bonding layer 125. A width w2 of the uppermost upper heat dissipation pattern 162 (in X-axis direction) may be greater than a width w1 of the uppermost upper redistribution layer 152 (in X-axis direction).

The upper heat dissipation vias 163 may be in (e.g., may vertically extend in or penetrate) the upper insulating layer 151 and (physically) connect the upper heat dissipation patterns 162. A width 163w of the upper heat dissipation vias 163 in a horizontal direction (e.g., X-axis direction or Y-axis direction) may be substantially the same as the width 153w of the upper redistribution vias 153 in the horizontal direction (e.g., X-axis direction or Y-axis direction), but the present inventive concept is not limited thereto. The width 153w of the upper redistribution vias 153 may refer to a width of an upper surface of the upper redistribution vias 153 (e.g., an upper surface of an uppermost upper redistribution via 153) in a horizontal direction (e.g., X-axis direction or Y-axis direction). The width 163w of the upper heat dissipation vias 163 may refer to a width of an upper surface of the upper heat dissipation vias 163 (e.g., an upper surface of an uppermost upper heat dissipation vias 163) in a horizontal direction (e.g., X-axis direction or Y-axis direction). In some embodiments, an upper surface of the upper heat dissipation vias 163 and an upper surface of the upper redistribution vias 153 that are disposed at the same level or substantially the same level may have the same or substantially the same width in a horizontal direction. The upper heat dissipation vias 163 may include a first upper heat dissipation via 163a connecting a lowermost upper heat dissipation pattern 162 among the upper heat dissipation patterns 162 and the conductive bonding layer 125 (e.g., the copper layer 127) to each other, and a second upper heat dissipation via 163b connecting upper heat dissipation patterns 162 located at different levels to each other. A width 163aw of the first upper heat dissipation via 163a may be substantially the same as the width 163bw of the second upper heat dissipation via 163b, but the present inventive concept is not limited thereto. The width 163aw may refer to a width of an upper surface of the first upper heat dissipation via 163a in a horizontal direction (e.g., X-axis direction or Y-axis direction). The width 163bw may refer to a width of an upper surface of the second upper heat dissipation via 163b in a horizontal direction (e.g., X-axis direction or Y-axis direction). The first upper heat dissipation via 163a may overlap the conductive bonding layer 125 in the vertical direction (e.g., Z-axis direction). The upper heat dissipation vias 163 may include, for example, copper (Cu), aluminum (Al), silver (Ag), tin (Sn), gold (Au), nickel (Ni), lead (Pb), titanium (Ti), and/or a material including alloys thereof. The upper heat dissipation vias 163 may be filled vias in which an interior of a via hole is filled (e.g., entirely filled) with a metal material, or may be conformal vias in which a metal material extends along an inner wall of a via hole (or a metal material partially fills a via hole).

The heat dissipation structure 160 including the upper heat dissipation patterns 162 and the upper heat dissipation vias 163 may be physically spaced apart from the upper redistribution structure 150 including the upper redistribution layers 152 and the upper redistribution vias 153. The heat dissipation structure 160 may not be in contact with the upper redistribution structure 150.

The external connection bumps 170 may be disposed below the lower redistribution structure 110. For example, the external connection bumps 170 may be on a lower surface of the lower insulating layer 111. The external connection bumps 170 may be electrically connected to the semiconductor chip 121 and the interconnection structure 130 through the lower redistribution layers 112. The semiconductor package 10 may be connected (e.g., electrically connected) to an external device such as a module substrate, system board, or the like through external connection bumps 170. For example, the external connection bumps 170 may include a low-melting point metal such as tin (Sn) or an alloy containing tin (Sn) (e.g., Sn—Ag—Cu). Depending on the embodiment, the external connection bumps 170 may have a shape which is a combination of a pillar (or underbump metal) and a ball. The pillar may include, for example, copper (Cu) or an alloy of copper (Cu), and the ball may include, for example, a solder ball. Depending on the embodiment, the lower insulating layer 111 may include a resist layer protecting the external connection bumps 170 from external physical and chemical damage.

The heat dissipation member 180 may be disposed on the upper redistribution structure 150, and connected to the heat dissipation structure 160. Referring to FIG. 1B, the heat dissipation member 180 may be disposed on at least one side of the second semiconductor package 200 (in a plan view). In an example embodiment, the heat dissipation member 180 may be provided in plural, and may be disposed on both (e.g., opposite) sides of the second semiconductor package 200 (in a plan view) or may surround all four surfaces of the second semiconductor package 200 (in a plan view). For example, the heat dissipation member 180 may be adjacent at least one side surface of the second semiconductor package 200. Depending on the embodiment, a dispositional relationship between the second semiconductor package 200 and the heat dissipation member 180 may change in various ways. The heat dissipation member 180 may control (e.g., reduce) warpage of the semiconductor package 10, and discharge heat generated by the first semiconductor package 100 externally. The heat dissipation member 180 may include a thermal interface material (TIM) layer 181 and a heat slug 182. The thermal interface material layer 181 may be disposed on the uppermost upper heat dissipation pattern 162 disposed on the upper insulating layer 151. The thermal interface material layer 181 may include, for example, a thermally conductive adhesive tape, a thermally conductive grease, a thermally conductive adhesive, and/or the like. The heat slug 182 may be disposed on the thermal interface material layer 181. The heat slug 182 may include a material with excellent thermal conductivity, such as aluminum (Al), gold (Au), silver (Ag), copper (Cu), iron (Fe), graphite, graphene, and/or the like, but is not limited thereto. Depending on the embodiment, an insulating resin (not shown) may be disposed (e.g., filled) between the heat dissipation member 180 and the second semiconductor package 200.

In the semiconductor package 10, heat generated by the semiconductor chip 121 may be conducted along (transferred through) the conductive bonding layer 125—the heat dissipation structure 160 including the upper heat dissipation patterns 162 and the upper heat dissipation vias 163—the heat dissipation member 180, and the heat dissipation function of the semiconductor package 10 may be improved, thereby providing a semiconductor package (e.g., the semiconductor package 10) having improved reliability.

The second semiconductor package 200 may be disposed on the first semiconductor package 100 to be spaced apart from the heat dissipation member 180 and may include a redistribution substrate 211, a second semiconductor chip structure 220, and a second encapsulant 240. The redistribution substrate 211 may be on the upper redistribution structure 150 (e.g., the uppermost upper redistribution layer 152). The redistribution substrate 211 may include a lower pad 212 and an upper pad 213 on lower and upper surfaces thereof, respectively, which can be electrically connected to the outside (e.g., outside of the redistribution substrate 211). In addition, the redistribution substrate 211 may include a redistribution circuit 214 electrically connecting the lower pad 212 and the upper pad 213.

The second semiconductor chip structure 220 may be mounted on the redistribution substrate 211 using a wire bonding or flip chip bonding method. The second semiconductor chip structure 220 may include a plurality of second semiconductor chips 222 stacked vertically. For example, the plurality of second semiconductor chips 222 may be stacked on the redistribution substrate 211 in a vertical direction (e.g., in Z-axis direction), and may be (electrically) connected to the upper pad 213 of the redistribution substrate 211 by a bonding wire (WB). The second semiconductor chip structure 220 may include a chip bonding film 221 disposed between the plurality of second semiconductor chips 222 or between the second semiconductor chip 222 and the redistribution substrate 211. In an example, the second semiconductor chip structure 220 (e.g., the plurality of second semiconductor chips 222) may include a memory chip, and the first semiconductor chip structure 120 (e.g., the first semiconductor chip 121) may include an AP chip. The redistribution substrate 211 may be a substrate on which the second semiconductor chip structure 220 is mounted.

Although it is schematically illustrated in FIG. 1A, the redistribution substrate 211, the lower pad 212, the upper pad 213, and the redistribution circuit 214 may have the same or similar characteristics as the lower redistribution structure 110. For example, the redistribution substrate 211 may include a ground (GND) pattern, a power (PWR) pattern, and a signal(S) pattern. Here, the signal(S) pattern may be defined as a transmission path for various signals, for example, data signals, and the like, excluding the ground (GND) pattern, power (PWR) pattern, and the like.

The second encapsulant 240 may be on (e.g., cover or overlap) at least a portion of the second semiconductor chip structure 220 on the redistribution substrate 211, and may have the same or similar characteristics as the encapsulant 140.

Connection conductors 270 may be disposed below the redistribution substrate 211. The connection conductors 270 may be between the redistribution substrate 211 and the upper redistribution structure 150 (e.g., the uppermost upper redistribution layer 152). The connection conductors 270 may be connected to the upper redistribution layers 152 on the upper insulating layer 151 and may be electrically connected to the upper redistribution layers 152. For example, the connection conductors 270 may include a low-melting point metal such as tin (Sn) or an alloy containing tin (Sn) (e.g., Sn—Ag—Cu). Depending on an example embodiment, the connection conductors 270 may have a shape, which is a combination of a pillar (or underbump metal) and a ball. The pillar may include, for example, copper (Cu) or an alloy of copper (Cu), and the ball may include, for example, a solder ball.

In the following description, descriptions overlapping those described with reference to FIGS. 1A to 1D may be omitted. In addition, overlapping descriptions in each embodiment may be omitted.

FIGS. 2A and 2B are enlarged views of example embodiments of region ‘A’ in FIG. 1A.

Referring to FIG. 2A together with FIG. 1A, a width 163w′ of (each of) upper heat dissipation vias 163 in a horizontal direction (e.g., X-axis direction or Y-axis direction) may be larger than a width 153w of (each of) the upper redistribution vias 153 in the horizontal direction. In some embodiments, at least one of the upper heat dissipation vias 163 may be formed to have a larger width than at least one of the upper redistribution vias 153 to improve heat dissipation function. The width 163w′ of the upper heat dissipation vias 163 may refer to a width of an upper surface of the upper heat dissipation vias 163 (e.g., an upper surface of an uppermost upper heat dissipation via 163) in a horizontal direction (e.g., X-axis direction or Y-axis direction).

Referring to FIG. 2B together with FIG. 1A, a width 163aw′ of the first upper heat dissipation via 163a′ connected to the conductive bonding layer 125 (e.g., the copper layer 127) may be greater than a width 163bw of the second upper heat dissipation via 163b connecting upper heat dissipation patterns 162 located at different levels to each other. The first upper heat dissipation via 163a′ may be equivalent to the first upper heat dissipation via 163a in FIG. 1D. For example, the width 163aw′ may refer to a width of an upper surface of the first upper heat dissipation via 163a′ in a horizontal direction (e.g., X-axis direction or Y-axis direction). The first upper heat dissipation via 163a′ may connect the conductive bonding layer 125 (e.g., the copper layer 127) and the lowermost upper heat dissipation pattern 162 among the upper heat dissipation patterns 162. The width and number of each of the upper heat dissipation vias 163 may be changed in various ways to improve heat dissipation characteristics.

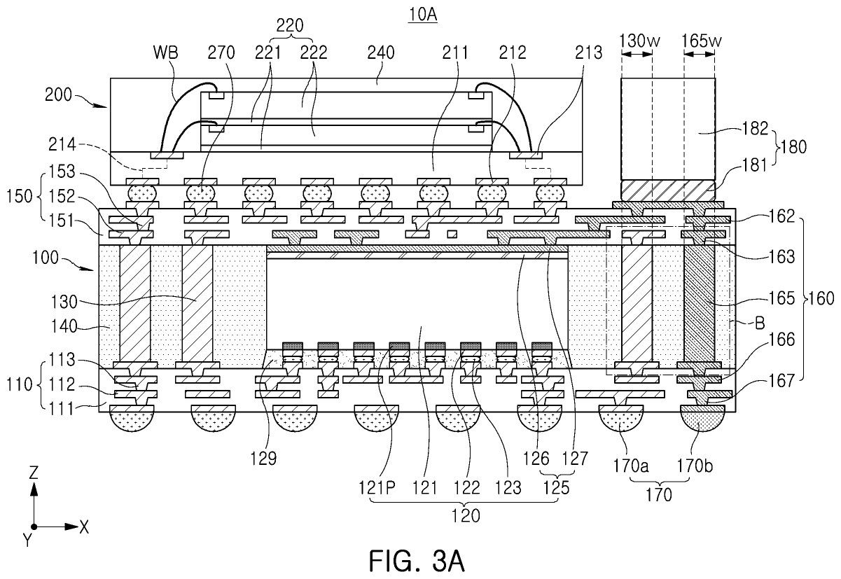

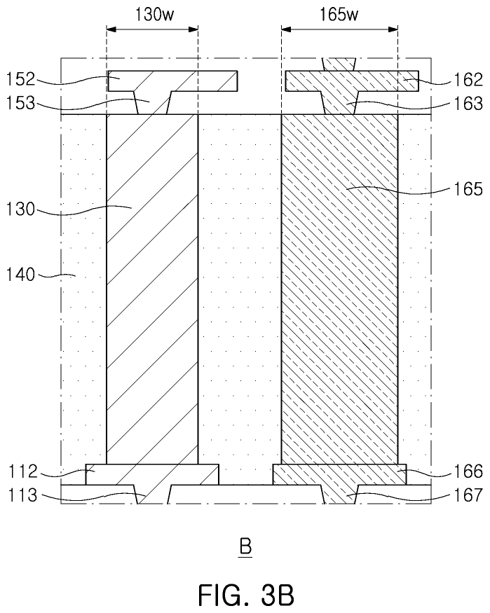

FIG. 3A is a cross-sectional view illustrating a semiconductor package 10A according to example embodiments, and FIG. 3B is an enlarged view of an example embodiment of region ‘B’ of FIG. 3A.

Referring to FIG. 3A, a heat dissipation structure 160 of the semiconductor package 10A may include an upper heat dissipation pattern 162 and upper heat dissipation vias 163, and may further include a vertical heat dissipation structure 165, lower heat dissipation patterns 166, and lower heat dissipation vias 167.

The lower heat dissipation patterns 166 may be disposed on or within the lower insulating layer 111, and the lower heat dissipation vias 167 may connect the lower heat dissipation patterns 166 to each other. The lower heat dissipation patterns 166 and lower heat dissipation vias 167 may have the same or similar characteristics as the upper heat dissipation patterns 162 and the upper heat dissipation vias 163, respectively.

The vertical heat dissipation structure 165 may be in (e.g., extend in or penetrate through) the encapsulant 140 and connect the upper heat dissipation patterns 162 (or the upper heat dissipation vias 163) and lower heat dissipation patterns 166 (or the lower heat dissipation vias 167) to each other. The vertical heat dissipation structure 165 may extend in a vertical direction (e.g., Z-axis direction) within the encapsulant 140. An upper surface of the vertical heat dissipation structure 165 may be exposed from the encapsulant 140, and may be substantially on the same surface (coplanar) as the upper surface of the encapsulant 140. The upper surface of the vertical heat dissipation structure 165 may not be covered by the encapsulant 140. For example, the vertical heat dissipation structure 165 may have a post (or pillar) shape extending in (or penetrating through) the encapsulant 140. A width 165w of the vertical heat dissipation structure 165 may be substantially the same as the width 130w of the interconnection structure 130. The width 165w may refer to a width of an upper surface of the vertical heat dissipation structure 165 in a horizontal direction (e.g., X-axis direction or Y-axis direction). The width 130w may refer to a width of an upper surface of the interconnection structure 130 in the horizontal direction (e.g., X-axis direction or Y-axis direction). However, the shape of the vertical heat dissipation structure 165 is not limited thereto. The vertical heat dissipation structure 165 may include, for example, a metal material such as copper (Cu). Depending on the embodiment, a metal seed layer (not shown) containing, for example, titanium (Ti), copper (Cu), or the like, may be formed on a lower surface of the vertical heat dissipation structure 165.

The external connection bumps 170 may include a first group of external connection bumps 170a connected (e.g., electrically connected) to the lower redistribution layers 112 and a second group of external connection bumps 170b connected to the lower heat dissipation patterns 166.

In the semiconductor package 10A of FIG. 3A, heat generated by the semiconductor chip 121 may be conducted through (transferred through) the conductive bonding layer 125—the upper heat dissipation patterns 162 and upper heat dissipation vias 163—the heat dissipation member 180—the upper heat dissipation patterns 162 and upper heat dissipation vias 163—the vertical heat dissipation structure 165—the lower heat dissipation patterns 166 and lower heat dissipation vias 167—the second group of external connection bumps 170b and may be discharged externally.

Referring to FIG. 3B together with FIG. 3A, a width 165w of the vertical heat dissipation structure 165 may be larger than the width 130w of the interconnection structure 130. As the vertical heat dissipation structure 165 has a larger width than the interconnection structure 130, the heat dissipation function of the heat dissipation structure 160 may be improved. The width and number of vertical heat dissipation structures 165 may be changed in various ways to improve heat dissipation characteristics.

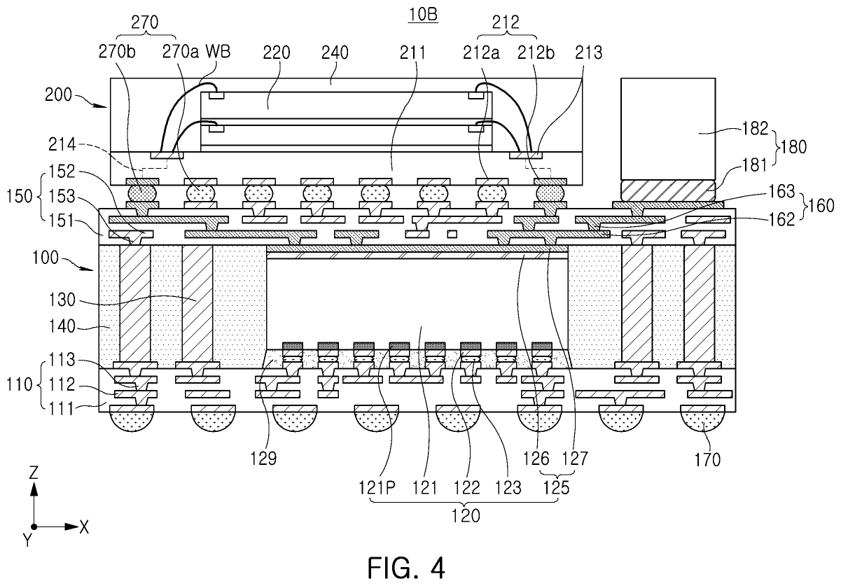

FIG. 4 is a cross-sectional view illustrating a semiconductor package 10B according to example embodiments.

Referring to FIG. 4, a heat dissipation structure 160 of the semiconductor package 10B may contact not only a heat dissipation member 180 but also a second semiconductor package 200. Connection conductors 270 of the second semiconductor package 200 may include a first group of connection conductors 270a, which is connected (e.g., electrically connected) to the upper redistribution layer 152 on the upper insulating layer 151, and a second group of connection conductors 270b, which is connected to the upper heat dissipation pattern 162 on the upper insulating layer 151. The first group of connection conductors 270a may be connected (e.g., electrically connected) to a first group of lower pads 212a and may be connected (e.g., electrically connected) to a signal pattern and/or power pattern in the redistribution substrate 211, and the second group of connection conductors 270b may be connected (e.g., electrically connected) to a second group of lower pads 212b and may be connected (e.g., electrically connected) to a ground pattern in the redistribution substrate 211. In the semiconductor package 10B, heat generated by the semiconductor chip 121 may be conducted through (transferred through) the conductive bonding layer 125—a heat dissipation structure including the upper heat dissipation patterns 162 and the upper heat dissipation vias 163—the heat dissipation member 180 and/or the second group of connection conductors 270b and may be discharged externally. In an example embodiment, the heat dissipation structure 160 may further include a vertical heat dissipation structure 165, lower heat dissipation patterns 166, and lower heat dissipation vias 167, like the semiconductor package 10A of FIG. 3A, so that heat may be discharged through various paths.

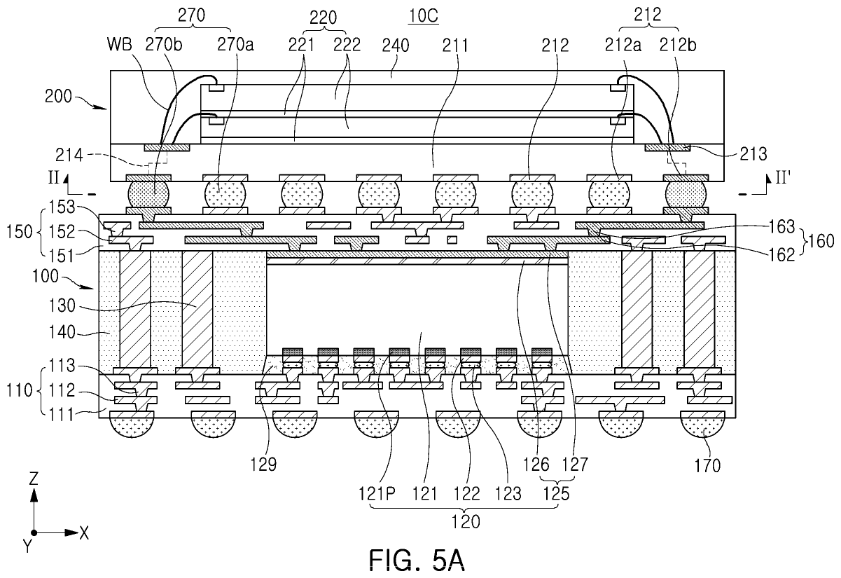

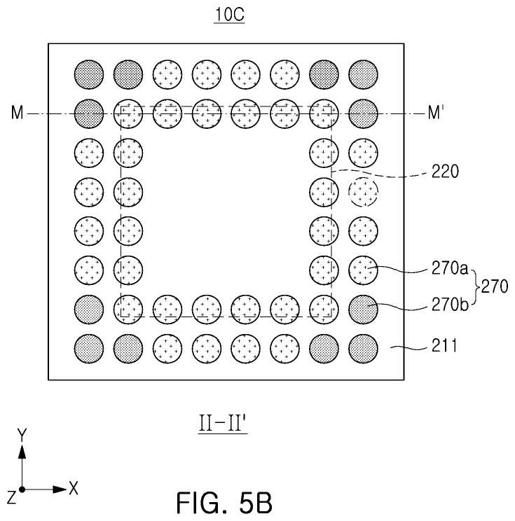

FIG. 5A is a cross-sectional view illustrating a semiconductor package 10C according to example embodiments. FIG. 5B illustrates a cross-section cut along the cutting line II-II′ of FIG. 5A. A cross-section cut along the cutting line M-M′ in FIG. 5B can be illustrated as (at least a portion of) FIG. 5A.

Referring to FIG. 5A, unlike the semiconductor package 10 of FIG. 1A, the semiconductor package 10C may not have a heat dissipation member 180. The second semiconductor package 200 may include a first group of connection conductors 270a, which is connected (e.g., electrically connected) to the upper redistribution layer 152, and a second group of connection conductors 270b connected (e.g., electrically connected) to the upper heat dissipation pattern 162. FIG. 5B is a plan view schematically illustrating connection conductors 270 disposed below the second semiconductor package 200 (e.g., disposed between the second semiconductor package 200 and the upper redistribution structure 150), and the disposition, number, size, and the like of the connection conductors 270 may be changed in various ways. Referring to FIG. 5B, in some embodiments, the second group of connection conductors 270b of the semiconductor package 10C may be disposed near (adjacent or nearest) an edge (or a side surface) of the second semiconductor package 200 (e.g., an edge or a side surface of the redistribution substrate 211), and the edge (or the side surface) of the second semiconductor package 200 may be relatively vulnerable to warpage. However, the number, size, dispositional relationship, and the like of the first group of connection conductors 270a and the second group of connection conductors 270b may be changed in various ways.

In the semiconductor package 10C of the present embodiment, heat generated by the semiconductor chip 121 may be conducted through (transferred through) the conductive bonding layer 125—the heat dissipation structure 160 including the upper heat dissipation patterns 162 and the upper heat dissipation vias 163—the second group of connection conductors 270b, and may be discharged externally.

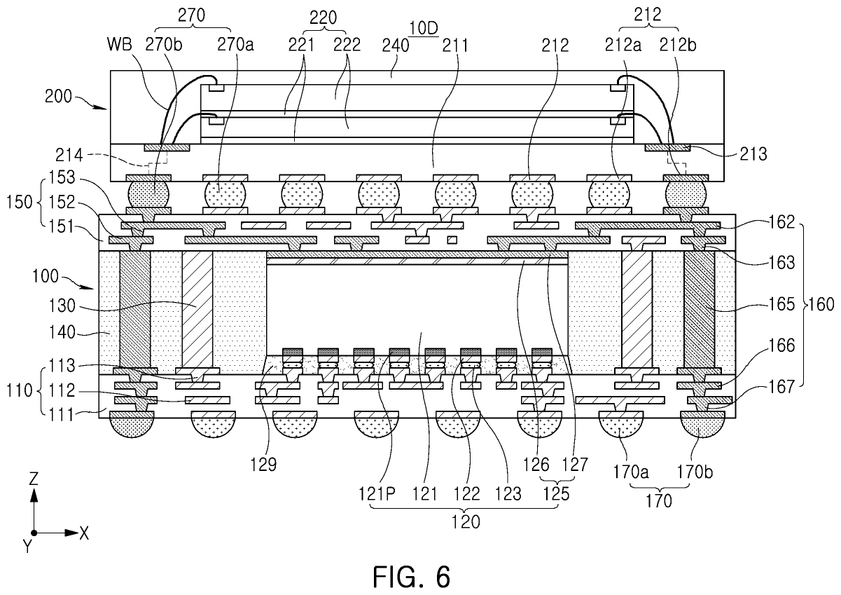

FIG. 6 is a cross-sectional view illustrating a semiconductor package 10D according to example embodiments.

Referring to FIG. 6, a heat dissipation structure 160 of the semiconductor package 10D, unlike the semiconductor package 10C of FIG. 6, may further include a vertical heat dissipation structure 165, lower heat dissipation patterns 166, and lower heat dissipation vias 167. In the semiconductor package 10D of the present embodiment, heat generated by the semiconductor chip 121 may be conducted through (transferred through) the conductive bonding layer 125—the upper heat dissipation patterns 162 and upper heat dissipation vias 163—the second group of connection conductors 270b—the vertical heat dissipation structure 165—the lower heat dissipation patterns 166 and lower heat dissipation vias 167—the second group of external connection bumps 170b and may be discharged externally.

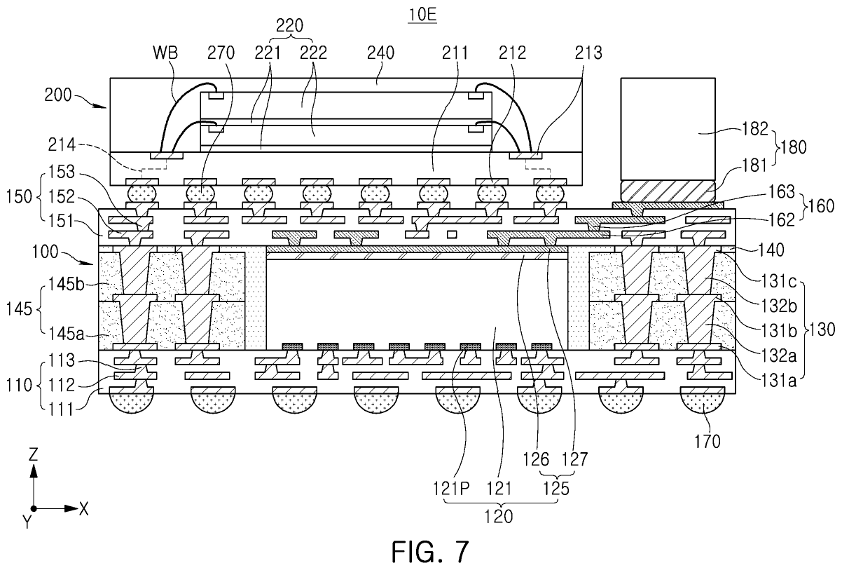

FIG. 7 is a cross-sectional view illustrating a semiconductor package 10E according to example embodiments.

Referring to FIG. 7, in the semiconductor package 10E, an interconnection structure 130 may be disposed around the semiconductor chip structure 120, and may include first, second, and third intermediate wiring layers 131a, 131b, and 131c and first and second intermediate wiring vias 132a and 132b. For example, the interconnection structure 130 may be on a side surface of the semiconductor chip structure 120. The semiconductor package 10E may further include an intermediate insulating layer 145 on (e.g., covering or overlapping) (at least a portion of) the interconnection structure 130. In some embodiments, the interconnection structure 130 may be spaced apart from the semiconductor chip structure 120 by the intermediate insulating layer 145 and/or the encapsulant 140.

The intermediate insulating layer 145 may extend around (e.g., surround) at least a portion of the interconnection structure 130, and the encapsulant 140 may be on (e.g., cover or overlap) (at least a portion of) each of the interconnection structure 130 and the intermediate insulating layer 145. The intermediate insulating layer 145 may include a first intermediate insulating layer 145a disposed on an upper surface of the lower redistribution structure 110 and a second intermediate insulating layer 145b disposed on an upper surface of the first intermediate insulating layer 145a. The first intermediate wiring layer 131a may be in a the first intermediate insulating layer 145a, the second intermediate wiring layer 131b may be disposed on an upper surface of the first intermediate insulating layer 145a, and the third intermediate wiring layer 131c may be disposed on an upper surface of the second intermediate insulating layer 145b. A lower surface of the first intermediate wiring layer 131a may be exposed from the first intermediate insulating layer 145a. The lower surface of the first intermediate wiring layer 131a may not be covered by the first intermediate insulating layer 145a. For example, the lower surface of the first intermediate wiring layer 131a may be (substantially) coplanar with a lower surface of the first intermediate insulating layer 145a. The first intermediate wiring via 132a may be in (e.g., extend in or penetrate through) the first intermediate insulating layer 145a and connect (e.g., electrically connect) the first and second intermediate wiring layers 131a and 131b, and the second intermediate wiring via 132b may be in (e.g., extend in or penetrate through) the second intermediate insulating layer 145b and connect (e.g., electrically connect) the second and third intermediate wiring layers 131b and 131c.

The encapsulant 140 may be on (e.g., cover or overlap) (at least a portion of) the intermediate insulating layer 135. An upper surface of the encapsulant 140, an upper surface of the third intermediate wiring layer 131c, and an upper surface of the conductive bonding layer 125 may be (substantially) coplanar. Other features of a semiconductor package 10E that are not specifically described here may have the same or similar features as those of the semiconductor package 10 described with reference to FIG. 1A.

Referring to FIG. 7 together with FIG. 3A, the semiconductor package 10E may further include a vertical heat dissipation structure (e.g., the vertical heat dissipation structure 165) extending in (or penetrating through) the encapsulant 140 and the intermediate insulating layer 145, lower heat dissipation patterns (e.g., the lower heat dissipation patterns 166) in the lower insulating layer 111, and lower heat dissipation vias (e.g., the lower heat dissipation vias 167), and heat generated by the semiconductor chip 121 may be discharged through a lower portion of the first semiconductor package 100 by the heat dissipation structure 160.

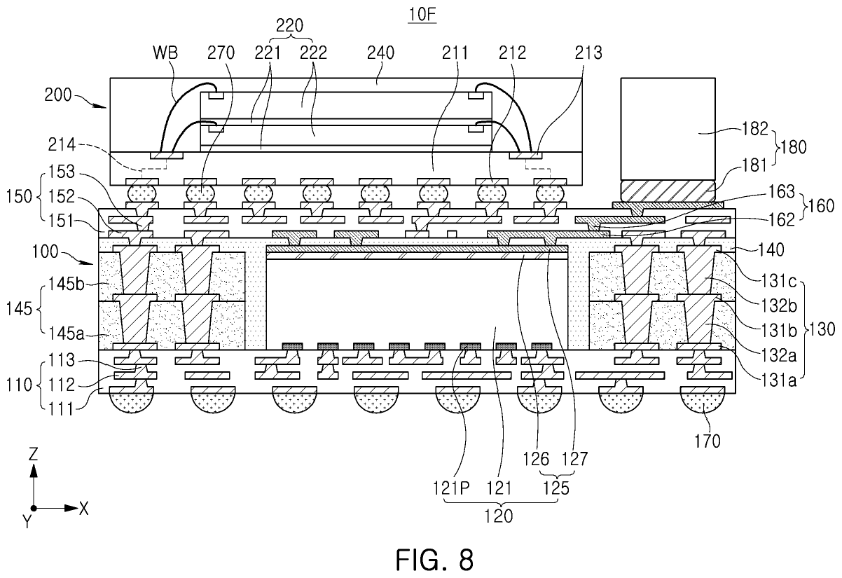

FIG. 8 is a cross-sectional view illustrating a semiconductor package 10F according to example embodiments.

Referring to FIG. 8, unlike the semiconductor packages described with reference to FIGS. 1A to 7, in the semiconductor package 10F, a conductive bonding layer 125 and an upper insulating layer 151 may be spaced apart from each other, while an encapsulant 140 may be on (e.g., cover or overlap) an upper surface of the conductive bonding layer 125 (e.g., an upper surface of the copper layer 127). For example, the conductive bonding layer 125 may be spaced apart from the upper insulating layer 151 by the encapsulant 140. An upper heat dissipation via 163 may extend in (e.g., penetrate through) the encapsulant 140 and contact the conductive bonding layer 125. Referring to FIG. 2B together with FIG. 8, in an example embodiment, a first upper heat dissipation via 163a′ in contact with the conductive bonding layer 125 may have a width in a horizontal direction (e.g., X-axis direction or Y-axis direction) greater than that of a second upper heat dissipation via 163b connecting upper heat dissipation patterns 162 located at different levels to each other within the upper insulating layer 151. In the semiconductor package 10F of the present embodiment, the upper heat dissipation via 163 extending in (e.g., penetrating through) the encapsulant 140 may be formed by partially etching the encapsulant 140 on the conductive bonding layer 125. Even in the case of the semiconductor packages 10A to 10D described with reference to FIGS. 1A to 7, according to an example embodiment, the encapsulant 140 may be on (e.g., cover or overlap) an upper surface of the conductive bonding layer 125, the conductive bonding layer 125 and the upper insulating layer 151 may be spaced apart from each other (by the encapsulant 140), and the upper heat dissipation via 163 may extend in (e.g., penetrate through) the encapsulant 140 and contact the conductive bonding layer 125.

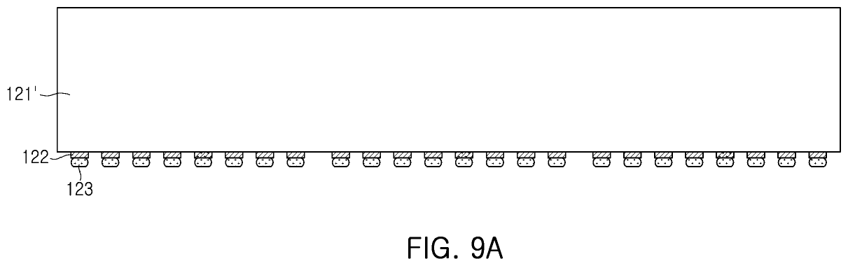

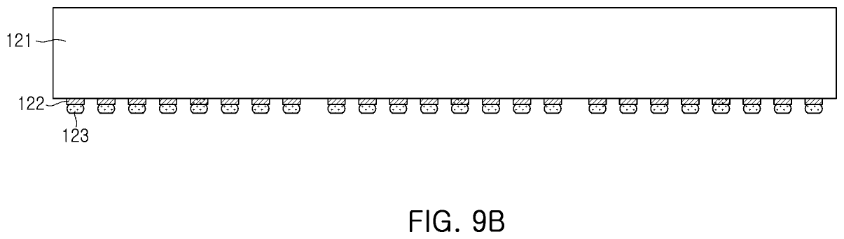

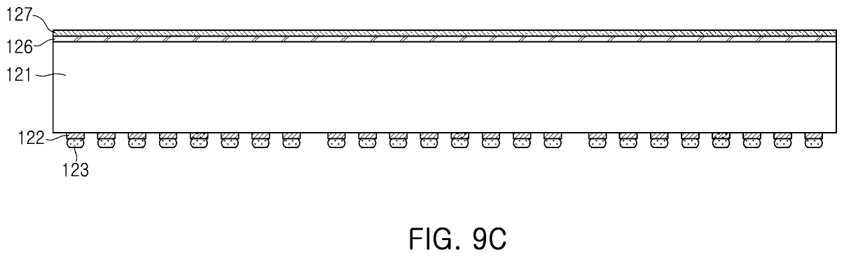

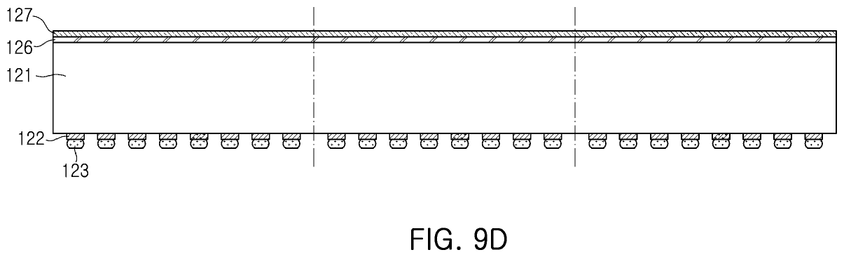

FIGS. 9A to 9D are diagrams of a process sequence illustrating a method for manufacturing a semiconductor chip structure according to example embodiments. FIGS. 9A to 9D illustrate a portion of the manufacturing process of the semiconductor chip structure 120 illustrated in FIG. 1A.

Referring to FIG. 9A, a connection pillar 122 and a connection solder 123 may be formed on a lower surface of a preliminary semiconductor chip 121′. The preliminary semiconductor chip 121′ may include a semiconductor wafer and/or a semiconductor integrated circuit (IC) including (e.g., formed of) a semiconductor element such as silicon, germanium, and/or a compound semiconductor such as silicon carbide (SiC), gallium arsenide (GaAs), indium arsenide (InAs), and indium phosphide (InP). The preliminary semiconductor chip 121′ may be a bare semiconductor chip without a separate bump or wiring layer, but the present inventive concept is not limited thereto.

Referring to FIG. 9B, an upper surface (or an upper portion) of the preliminary semiconductor chip 121′ may be etched to form a semiconductor chip 121. An etching process may include a grinding process, a chemical mechanical polishing (CMP) process, and the like. Through the present etching process, the semiconductor chip 121 may be formed to have a desired thickness.

Referring to FIG. 9C, a plurality of metal layers 126 and 127 may be formed on an upper surface of the semiconductor chip 121. The plurality of metal layers 126 and 127 may be formed using, for example, a sputtering process, a plating process, a physical vapor deposition (PVD) process, or a chemical vapor deposition (CVD) process. In an example embodiment, the plurality of metal layers 126 and 127 may include a titanium (Ti) layer 126 on the upper surface of the semiconductor chip 121 and a copper (Cu) layer 127 on the titanium (Ti) layer 126.

Referring to FIG. 9D, a cut process may be performed to cut the semiconductor chip into individual semiconductor chips 121. For example, the semiconductor chip 121 in FIG. 9C may be cut to form a plurality of smaller individual semiconductor chips 121 in FIG. 9D. One among the plurality of smaller individual semiconductor chips 121 in FIG. 9D may correspond to the semiconductor chip 121 in FIGS. 1A to 8. The cut process may be performed by a blade dicing process, a laser dicing process, and the like. Referring to FIG. 1A together with FIG. 9D, the cut semiconductor chip 121 (along with the connection pillar 122, the connection solder 123, the connection terminal 121P, and the conductive bonding layer 125) may form a semiconductor chip structure 120 mounted on the lower redistribution structure 110.

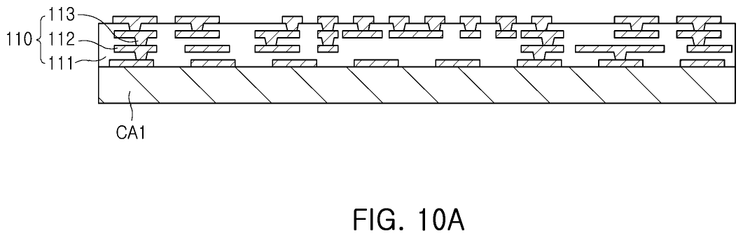

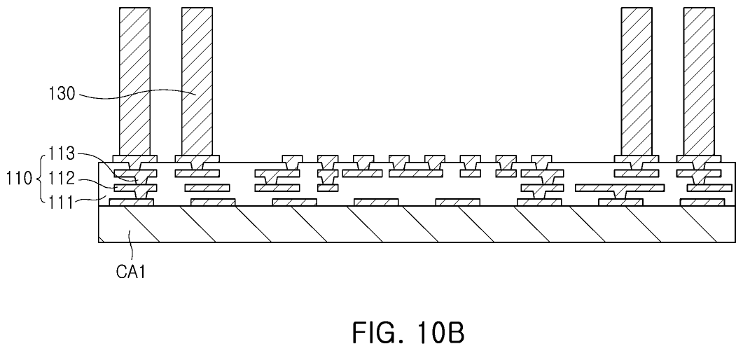

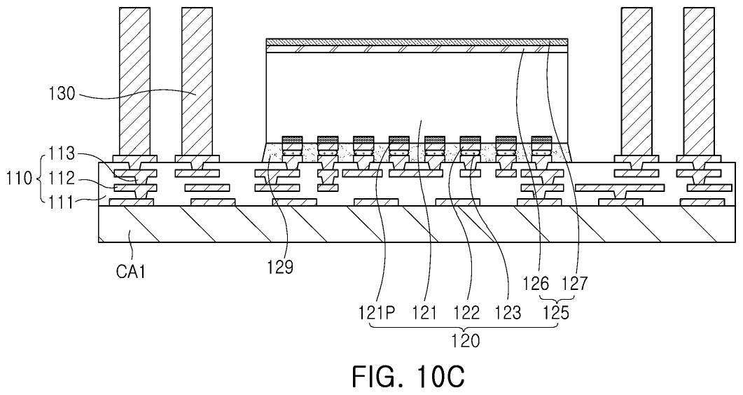

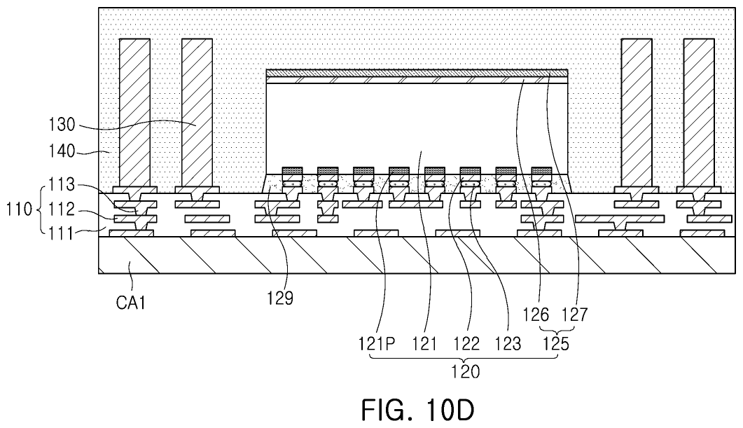

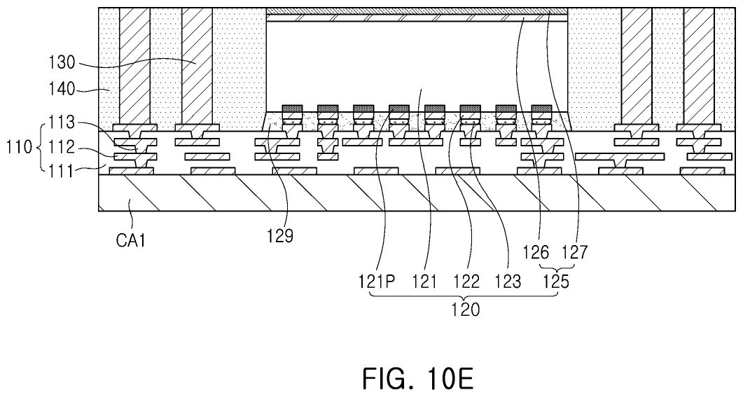

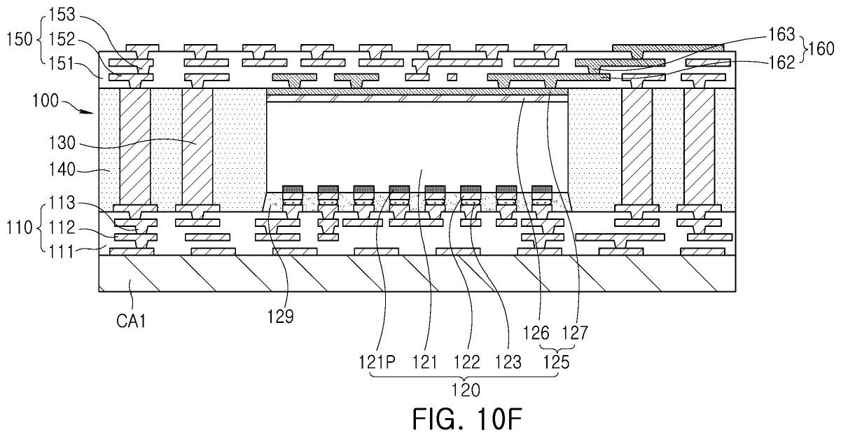

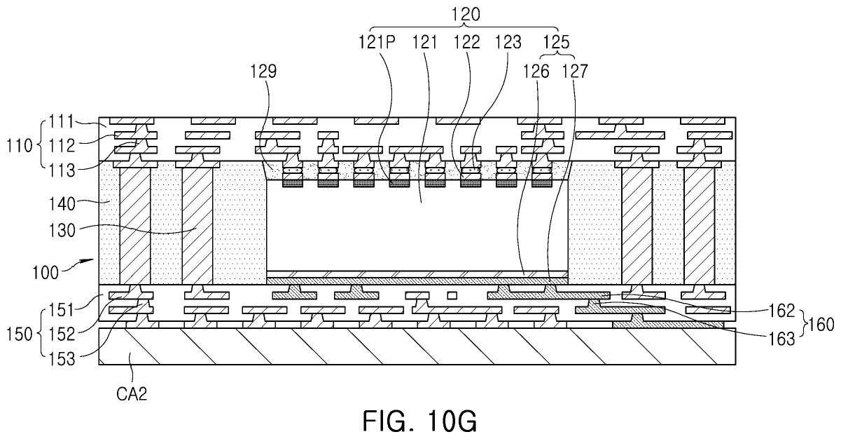

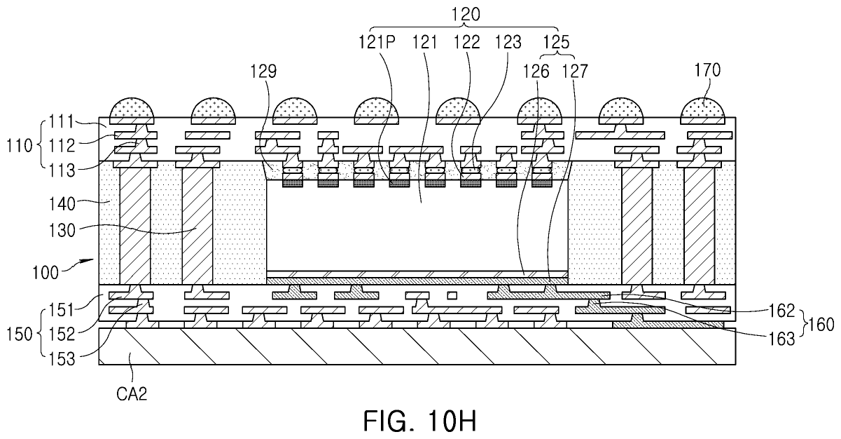

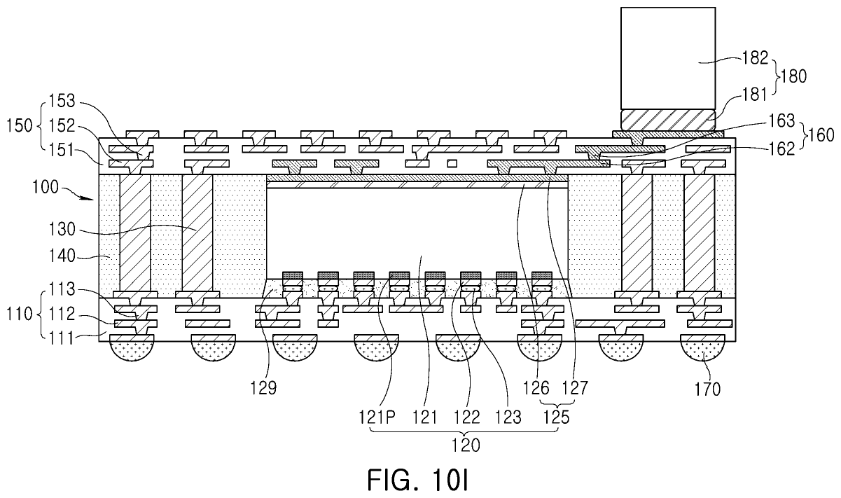

FIGS. 10A to 10I are diagrams of a process sequence illustrating a method of manufacturing a semiconductor package according to example embodiments. FIGS. 10A to 10I illustrate a method of manufacturing the semiconductor package 10 of FIG. 1A.

Referring to FIG. 10A, a lower redistribution structure 110 may be formed on a first carrier CA1. For example, the first carrier CA1 may include a polymer layer, including a curable resin, a metal layer, including nickel (Ni), titanium (Ti), and/or the like, and a copper clad laminate (CCL). The polymer layer and the metal layer may be sequentially disposed (e.g., coated) on the copper clad laminate. The lower redistribution structure 110 may include a lower insulating layer 111, lower redistribution layers 112, and lower redistribution vias 113. The lower insulating layer 111 may be formed by sequentially applying (e.g., depositing) and curing a photosensitive material, for example, PID. The lower redistribution layers 112 and the lower redistribution vias 113 may be formed by performing an exposure process and a development process to form a via hole extending in (e.g., penetrating) the lower insulating layer 111, and formed by patterning a metal material on the lower insulating layer 111 using a plating process. The lower redistribution layers 112 may also be formed on an upper surface of the lower redistribution structure 110 (e.g., the lower insulating layer 111), and a barrier layer (not shown) including nickel (Ni), gold (Au), and the like may be formed (on the lower redistribution layers 112).

Referring to FIG. 10B, an interconnection structure 130 may be formed on the lower redistribution layers 112 formed on the lower insulating layer 111. The interconnection structure 130 may be formed by performing a plating process. The interconnection structure 130 may include a metal material such as copper (Cu). Depending on the embodiment, a metal seed layer (not shown) containing titanium (Ti), copper (Cu), and the like may be formed on a lower surface of the interconnection structure 130. For example, the metal seed layer may be between the lower surface of the interconnection structure 130 and the lower redistribution layer 112.

Referring to FIG. 10C, a semiconductor chip structure 120 may be mounted on the lower redistribution structure 110. The semiconductor chip structure 120 may be a semiconductor chip structure 120 formed by the manufacturing process described with reference to FIGS. 9A to 9D and may include a semiconductor chip 121 and a conductive bonding layer 125 on an upper surface of the semiconductor chip 121. The semiconductor chip structure 120 may be mounted using a flip-chip method. For example, the semiconductor chip structure 120 may be connected (e.g., electrically connected) to the lower redistribution layers 112 through a connection pillar 122 and a connection solder 123 formed on the connection terminal 121P. An underfill layer 129 may be formed between the semiconductor chip structure 120 and the lower redistribution structure 110. The underfill layer 129 may be formed using a capillary underfill CUF process, but the present inventive concept is not limited thereto.

Referring to FIG. 10D, an encapsulant 140 may be formed on (e.g., to cover, to overlap, or to encapsulate) at least a portion of each of the semiconductor chip structure 120 and the interconnection structure 130. An upper surface of the encapsulant 140 may be formed at a level higher than an upper surface of the interconnection structure 130. The encapsulant 140 may be formed, for example, by applying (e.g., depositing) and curing EMC.

Referring to FIG. 10E, a planarization process may be applied to an upper portion of the encapsulant 140. The planarization process may include a grinding process, a Chemical Mechanical Polishing (CMP) process, and the like. A portion of the interconnection structure 130 and the encapsulant 140 may be removed by etching process and/or the planarization process, and an upper end (e.g., an upper surface) of the conductive bonding layer 125 of the semiconductor chip structure 120 and an upper end (e.g., an upper surface) of the interconnection structure 130 may be exposed from an upper surface of the encapsulant 140. For example, the upper end (e.g., the upper surface) of the conductive bonding layer 125 of the semiconductor chip structure 120 and the upper end (e.g., the upper surface) of the interconnection structure 130 may not be covered by the encapsulant 140. Accordingly, a flat surface comprising the upper surface of the semiconductor chip structure 120, the upper surface of the interconnection structure 130, and the upper surface of the encapsulant 140 may be formed. In the present etching process, a portion of the conductive bonding layer 125 located above the semiconductor chip structure 120 may be removed together during the planarization process, and the conductive bonding layer 125 may function to protect the semiconductor chip 121 in the planarization process.

Referring to FIG. 10F, an upper redistribution structure 150 on (e.g., covering or overlapping) the upper surface of the encapsulant 140, the upper surface of the semiconductor chip structure 120, and the upper surface of the interconnection structure 130 may be formed. The upper redistribution structure 150 may be formed by a similar process as the lower redistribution structure 110. The upper insulating layer 151 may be formed by sequentially applying (e.g., depositing) and curing a photosensitive material, for example, PID. The upper redistribution layers 152 and the upper redistribution vias 153 may be formed by performing an exposure process and a development process to form a via hole extending (e.g., penetrating through) the upper insulating layer 151, and may be formed by patterning a metal material on the upper insulating layer 151 using a plating process. Upper heat dissipation patterns 162 and upper heat dissipation vias 163 of the heat dissipation structure 160 may be formed simultaneously with the upper redistribution layers 152 and upper redistribution vias 153 located at the same level, respectively. A barrier layer (not shown) may be formed on a pad portion (e.g., an upper surface of the upper redistribution layer 152) exposed on an upper surface of the upper redistribution structure 150.

Referring to FIG. 10G, a second carrier CA2 may be formed on the upper redistribution structure 150, and the package may be turned over to perform a subsequent process. The first carrier CA1 may be removed to expose an upper surface of the lower redistribution structure 110 (based on FIG. 10G), and a surface of the lower redistribution layers 112 located on the upper surface of the lower redistribution structure 110 (based on FIG. 10G) may be exposed.

Referring to FIG. 10H, external connection bumps 170 may be formed in contact with the exposed lower redistribution layers 112.

Referring to FIG. 10I, the package may be turned over again to perform a subsequent process. A heat dissipation member 180 may be formed on the upper heat dissipation pattern 162 disposed on the upper insulating layer 151. Referring to FIG. 1A together with FIG. 10I, a second semiconductor package 200, which is spaced apart from the heat dissipation member 180 may be disposed on the upper redistribution structure 150. The second semiconductor package 200 may be electrically connected to the upper redistribution layers 152 through connection conductors 270.

As set forth above, according to example embodiments of the present inventive concept, a semiconductor package having improved reliability may be provided by introducing a heat dissipation structure connected to a semiconductor chip.

The various and advantageous advantages and effects of the present inventive concept are not limited to the above description, and may be more easily understood in the course of describing the specific embodiments of the present inventive concept. While example embodiments have been shown and described above, it will be apparent to those skilled in the art that modifications and variations could be made without departing from the scope of the present inventive concept, as defined by the appended claims.

While example embodiments have been shown and described above, it is to be understood that the disclosure is not limited to them, but, on the contrary, is intended to cover various modifications and variations thereof without departing from the scope of the present inventive concept as defined by the appended claims.

What is claimed is:

1. A semiconductor package, comprising:
a semiconductor chip structure that includes a semiconductor chip and a conductive bonding layer on an upper surface of the semiconductor chip;
a lower redistribution structure on a lower surface of the semiconductor chip structure, wherein the lower redistribution structure includes a lower insulating layer and lower redistribution layers in the lower insulating layer;
external connection bumps on a lower surface of the lower redistribution structure, wherein the external connection bumps are electrically connected to the lower redistribution layers;
an encapsulant on the semiconductor chip structure and the lower redistribution structure;
an upper redistribution structure on the semiconductor chip structure, wherein the upper redistribution structure includes an upper insulating layer, upper redistribution layers in the upper insulating layer, and upper redistribution vias that electrically connect the upper redistribution layers to each other;
an interconnection structure in the encapsulant, wherein the interconnection structure electrically connects the lower redistribution layers and the upper redistribution layers;
a heat dissipation structure that includes upper heat dissipation patterns and upper heat dissipation vias, wherein the upper heat dissipation patterns are in the upper insulating layer, and the upper heat dissipation vias connect the conductive bonding layer and the upper heat dissipation patterns;
an upper package on the upper redistribution structure, wherein the upper package is electrically connected to the upper redistribution layers; and
a heat dissipation member on at least one side of the upper package, wherein the heat dissipation member is connected to the upper heat dissipation patterns.

2. The semiconductor package of claim 1, wherein an upper surface of the conductive bonding layer and an upper surface of the encapsulant are coplanar.

3. The semiconductor package of claim 1, wherein the conductive bonding layer overlaps an entirety of the upper surface of the semiconductor chip in a vertical direction that is perpendicular to an upper surface of the lower redistribution structure.

4. The semiconductor package of claim 1, wherein the conductive bonding layer includes a titanium layer and a copper layer,
wherein the titanium layer is in contact with the upper surface of the semiconductor chip, and
wherein the copper layer is on the titanium layer.

5. The semiconductor package of claim 1, wherein the upper heat dissipation vias include a first upper heat dissipation via that connects a lowermost upper heat dissipation pattern among the upper heat dissipation patterns and the conductive bonding layer to each other,
wherein the upper heat dissipation vias further include a second upper heat dissipation via that connects the upper heat dissipation patterns to each other,
wherein the upper heat dissipation patterns are located at different distances from the lower redistribution structure, and
wherein a width of an upper surface of the first upper heat dissipation via in a horizontal direction that is parallel with an upper surface of the lower redistribution structure is greater than a width of an upper surface of the second upper heat dissipation via in the horizontal direction.

6. The semiconductor package of claim 1, wherein a width of each of upper surfaces of the upper heat dissipation vias in a horizontal direction is greater than a width of each of upper surfaces of the upper redistribution vias in the horizontal direction.

7. The semiconductor package of claim 1, wherein an upper surface of the conductive bonding layer is in contact with the upper insulating layer.

8. The semiconductor package of claim 1, wherein the upper package includes a first group of connection conductors and a second group of connection conductors,
wherein the first group of connection conductors are electrically connected to the upper redistribution layers, and
wherein the second group of connection conductors are connected to the upper heat dissipation patterns.

9. The semiconductor package of claim 1, wherein the upper heat dissipation patterns and the upper heat dissipation vias each include copper and/or aluminum.

10. The semiconductor package of claim 1, wherein the upper heat dissipation patterns include an uppermost upper heat dissipation pattern on the upper insulating layer,
wherein the heat dissipation member includes a thermal interface material layer that is in contact with the uppermost upper heat dissipation pattern, and
wherein the heat dissipation member further includes a heat slug on the thermal interface material layer.

11. The semiconductor package of claim 10, wherein the heat slug includes aluminum, gold, silver, copper, and/or iron.

12. The semiconductor package of claim 1, wherein the heat dissipation structure further includes lower heat dissipation patterns and a vertical heat dissipation structure,
wherein the lower heat dissipation patterns are in the lower insulating layer,
wherein the vertical heat dissipation structure extends in the encapsulant and connects the upper heat dissipation patterns and the lower heat dissipation patterns,
wherein the external connection bumps include a first group of external connection bumps and a second group of external connection bumps,
wherein the first group of external connection bumps are electrically connected to the lower redistribution layers, and
wherein the second group of external connection bumps are connected to the lower heat dissipation patterns.

13. The semiconductor package of claim 12, wherein a width of the vertical heat dissipation structure in a horizontal direction that is parallel with an upper surface of the lower redistribution structure is greater than a width of the interconnection structure in the horizontal direction.

14. A semiconductor package, comprising:
a lower redistribution structure that includes lower redistribution layers;
a semiconductor chip structure on the lower redistribution structure;
an encapsulant on the semiconductor chip structure and the lower redistribution structure;
an upper redistribution structure that includes an upper insulating layer and upper redistribution layers, wherein the upper insulating layer is on the encapsulant, and the upper redistribution layers are on and within the upper insulating layer;
a heat dissipation structure that includes upper heat dissipation patterns and upper heat dissipation vias, wherein the upper heat dissipation patterns are on and within the upper insulating layer, and the upper heat dissipation vias are in the upper insulating layer; and
a heat dissipation member on the upper redistribution structure, wherein the heat dissipation member is connected to the upper heat dissipation patterns,
wherein the upper redistribution layers include an uppermost upper redistribution layer on the upper insulating layer,
wherein the upper heat dissipation patterns include an uppermost upper heat dissipation pattern on the upper insulating layer, and
wherein a width of an upper surface of the uppermost upper heat dissipation pattern is greater than a width of an upper surface of the uppermost upper redistribution layer.

15. The semiconductor package of claim 14, wherein an upper surface of the semiconductor chip structure is not overlapped by the encapsulant in a vertical direction that is perpendicular to an upper surface of the lower redistribution structure, and
wherein the upper insulating layer is in contact with the upper surface of the semiconductor chip structure.

16. The semiconductor package of claim 14, further comprising:
an interconnection structure adjacent the semiconductor chip structure, wherein the interconnection structure electrically connects the lower redistribution layers and the upper redistribution layers; and
an intermediate insulating layer that extends around at least a portion of the interconnection structure,
wherein the encapsulant is on at least a portion of each of the interconnection structure and the intermediate insulating layer.

17. The semiconductor package of claim 16, wherein the semiconductor chip structure includes a semiconductor chip and a conductive bonding layer on an upper surface of the semiconductor chip,
wherein the encapsulant is on the conductive bonding layer,
wherein the upper heat dissipation vias include a first upper heat dissipation via and a second upper heat dissipation via,
wherein the first upper heat dissipation via extends in the encapsulant and connects a lowermost upper heat dissipation pattern among the upper heat dissipation patterns and the conductive bonding layer to each other, and
wherein the second upper heat dissipation via connects ones among the upper heat dissipation patterns located at different distances from the lower redistribution structure.

18. A semiconductor package, comprising:
a first semiconductor package including
a first semiconductor chip structure;
a first encapsulant that extends around the first semiconductor chip structure;
an upper redistribution structure that includes an upper insulating layer and upper redistribution layers on and within the upper insulating layer, wherein the upper redistribution structure is on an upper surface of the first semiconductor chip structure and an upper surface of the first encapsulant;
a heat dissipation structure that includes upper heat dissipation patterns and upper heat dissipation vias, wherein the upper heat dissipation patterns are on and within the upper insulating layer, and the upper heat dissipation vias connect ones among the upper heat dissipation patterns to each other in the upper insulating layer; and
a second semiconductor package on the first semiconductor package,
wherein the second semiconductor package includes
a redistribution substrate that includes a signal pattern, a power pattern, and a ground pattern;
a second semiconductor chip structure on the redistribution substrate, wherein the second semiconductor chip structure is electrically connected to the signal pattern, the power pattern, and the ground pattern;
a second encapsulant on the second semiconductor chip structure; and
connection conductors on a lower surface of the redistribution substrate, wherein the connection conductors include a first group of connection conductors and a second group of connection conductors, the first group of connection conductors are electrically connected to at least one of the signal pattern and the power pattern, and the second group of connection conductors are electrically connected to the ground pattern,
wherein the first group of connection conductors are electrically connected to the upper redistribution layers, and
wherein the second group of connection conductors are connected to the heat dissipation structure.

19. The semiconductor package of claim 18, further comprising:
a heat dissipation member on the first semiconductor package,
wherein the heat dissipation member is spaced apart from the second semiconductor package, and
wherein the heat dissipation member is connected to the heat dissipation structure.

20. The semiconductor package of claim 18, wherein the second semiconductor chip structure includes a plurality of semiconductor chips stacked vertically.
